(19) United States
(12) Patent Application Publication
(10) Pub. No.: US 2026/0025117 A1
(43) Pub. Date: Jan. 22, 2026

(54) METHOD FOR MANUFACTURING BONDED BODY

(71) Applicant: NGK INSULATORS, LTD., Nagoya-shi (JP)

(72) Inventor: Yuki ITO, Nagoya-shi (JP)

(21) Appl. No.: 19/341,066

(22) Filed: Sep. 26, 2025

Related U.S. Application Data
(63) Continuation of application No. PCT/JP2023/040884, filed on Nov. 14, 2023.

(30) Foreign Application Priority Data
Mar. 28, 2023 (JP) 2023-051421

(51) Int. Cl. H03H 3/08; H03H 9/02; H03H 9/25

(52) U.S. Cl. CPC H03H 3/08; H03H 9/02559; H03H 9/02574; H03H 9/25

(57) ABSTRACT

An intermediate layer is provided on a first main face of a piezoelectric material substrate having the first main face and a second main face, to obtain a laminated body. At this time, the first main face is roughened. The laminated body is subjected to double-side polishing to polish the second main face of the piezoelectric material substrate and a bonding face of the intermediate layer. The bonding face of the intermediate layer is bonded with a supporting substrate. In the polishing step, the ratio of the average polished amount of an outer peripheral part of the intermediate layer with respect to the average polished amount of the inner part of the intermediate layer (average polished amount of outer peripheral part/average polished amount of inner part) is 1.1 or higher and 1.2 or lower.

### CROSS-REFERENCE TO RELATED APPLICATIONS

This application is a continuation application of PCT/JP2023/040884, filed Nov. 14, 2023, which claims priority to Japanese Application No. JP 2023-051421 filed on Mar. 28, 2023, the entire contents all of which are incorporated hereby by reference.

### TECHNICAL FIELD

The present invention is related to a method of providing a bonded body preferably utilized for an acoustic wave element or the like.

### BACKGROUND ARTS

An acoustic surface wave device, which can be functioned for a filter device or vibrator contained in a mobile phone or the like, or a surface acoustic wave device such as a Lamb wave device or film bulk acoustic resonator (FBAR) including a piezoelectric thin film have been known. It is known an acoustic wave device provided by adhering a supporting substrate and a piezoelectric material substrate propagating surface acoustic wave and by providing a comb electrode capable of oscillating the surface acoustic wave on a surface of the piezoelectric material substrate.

It is reported that, in a bonded substrates used for a surface acoustic wave device, the surface of a piezoelectric material substrate is made a roughened surface to reduce spurious (Patent documents 1 and 2). Further, it is known that the surface of the piezoelectric substrate is made the roughened surface, a filler layer is provided onto the roughened surface to flatten it and the filler layer is adhered to a silicon substrate through an adhesive layer. According to the method, epoxy and acrylic resins are utilized for the filler layer and adhesive layer and the bonding face of the piezoelectric material substrate is made the roughened surface, so that the reflection of a bulk wave is suppressed and spurious is reduced. Further, as irregularities on the roughened surface of the piezoelectric material substrate are filled and flattened followed by the adhesion, air bubbles are prevented from incorporating into the adhesive layer. (Prior technical documents)

### PATENT DOCUMENTS

(Patent document 1) Japanese Patent No. 5814727 B
(Patent document 2) Japanese Patent No. 6427712 B
(Patent document 3) Japanese Patent No. 6747599 B

### SUMMARY OF THE INVENTION

Until now, a single-side polishing machine is applied for mirror-polishing of the bonding face of the intermediate layer, for directly bonding the supporting substrate and intermediate layer formed on the piezoelectric material substrate with the roughened surface. However, according to the single-side polishing, there are the problems that the number of wafers to be processed during a single process is low and that the wafer is susceptible to fracture during the mounting and removal on a polishing jig.

Then, the inventors have noticed double-side polishing enabling the processing of many piezoelectric material substrates at a single process and alleviating the need of fixing the piezoelectric material substrate onto the jig. The double-side polishing has been generally applied as one of polishing methods of a semiconductor silicon wafer and is the technique of containing the wafer in a carrier for holding the wafer and of polishing the both sides of the wafer (Patent document 3).

However, for example as shown in FIG. 3A, after an intermediate layer 2 is formed on a roughened surface of a piezoelectric material substrate of a bonded body 5 to provide a laminated body and the laminated body is subjected to polishing by means of a double-side polishing machine, in the case that the intermediate layer 2 is subjected to direct bonding with a separate supporting substrate, it is proved that separation may occur mainly in an outer peripheral edge of the intermediate layer 2. That is, in FIG. 3A, the separation may occur in an outer peripheral edge C of the intermediate layer 2. D represents a bonded part.

An object of the present invention is, after an intermediate layer is provided on a roughened surface of a piezoelectric material substrate and the piezoelectric material substrate and intermediate layer are subjected to double-side polishing, to suppress the separation of a bonded body when a bonding face of the intermediate layer is bonded with a supporting substrate.

The present invention provides a method of producing a bonded body, said method comprising:
an intermediate layer growing step of providing an intermediate layer on a first main face of a piezoelectric material substrate having the first main face and a second main face, the first main face being roughened;
a polishing step of subjecting said laminated body to double-side polishing to polish side second main face of said piezoelectric material substrate and a bonding face of said intermediate layer; and
a bonding step of bonding said bonding face of said intermediate layer to a supporting substrate,
wherein a ratio of an average polished amount of an outer peripheral part of said intermediate layer with respect to an average polished amount of an inner part of said intermediate layer (said average polished amount of said outer peripheral part/said average polished amount of said inner part) is 1.1 or higher and 1.2 or lower in said polishing step.

The present inventors have studied the cause of the separation mainly along the outer peripheral part of the intermediate layer in the case that the bonding face of the intermediate layer is bonded to the supporting substrate, after the intermediate layer is provided on the roughened surface of the piezoelectric material substrate and that the piezoelectric material substrate and intermediate layer are subjected to the double-side polishing. Such phenomenon has not occurred in the case of the double-side polishing of a silicon substrate.

During the study, in the case that the intermediate layer is provided on the roughened surface of the piezoelectric material substrate and that the piezoelectric material substrate and intermediate layer are subjected to the double-side polishing, it is observed the phenomenon that the polished amount of the central part is larger than that of the outer peripheral part of the intermediate layer. As the polished amount of the outer peripheral part is generally larger than that of the inner part in the case of polishing the silicon wafer, such opposite phenomenon is beyond expectation.

As such, in the case that the piezoelectric material substrate with the intermediate layer provided on the roughened surface is subjected to the double-side polishing, the polishing of the central part proceeds earlier than that of the outer peripheral part. It is considered that the roughened surface remains in the outer peripheral part when the mirror-polishing of the central part is completed and that the separation occurs in the outer peripheral part after the direct bonding.

In search for the solution of such problem, the present inventors have further studied the distribution of pressure applied on the piezoelectric material substrate and intermediate layer from a polishing pad. Conventionally, according to the double-side polishing, as the polishing pad is made of an elastic body, the pad tends to be deformed toward the outer peripheral part of the silicon wafer during the processing and the outer peripheral part is scraped stronger than the central part by the deformation of the pad toward the wafer. However, in the case that the intermediate layer is formed on the piezoelectric material substrate with the roughened surface, it is observed the phenomenon contrary to this.

Thus, it is researched the distribution of pressure applied on the laminated body during the processing. Specifically, while the laminated body is held in a carrier, a pressure-sensitive sheet composed of a piezoelectric element is positioned between the laminated body and a polishing surface plate and the laminated body is pressurized in static state. As a result, it is proved that the pressure is smaller in the outer peripheral part than in the central part of the intermediate layer. It is considered that the intermediate layer is formed on the piezoelectric material substrate to generate a stress within the film and to result in the warping of the thus obtained laminated body, generating pressure distribution different from the conventional pressure distribution. Further, it is confirmed that the ratio of the pressures in the central part and outer peripheral part is made lower by increasing the load during the processing. It is thus speculated that the pressure during the processing is increased to lessen the warping of the laminated body, resulting in the reduction of the difference of the pressures within the central part and outer peripheral part.

Based on the above findings, as shown in FIG. 3B, it is considered that an average polished amount of the outer peripheral part T of the intermediate layer 2 is made larger than an average polished amount of the inner part I in the double-side polishing of the laminated body. Specifically, by adjusting the ratio of the average polished amount of the outer peripheral part T of the intermediate layer 2 with respect to the average polished amount of the inner part I of the intermediate layer 2 (average polished amount of the outer peripheral part T/average polished amount of the inner part I) in a range of 1.1 or higher and 1.2 or lower, it is found that the separation from the supporting substrate after the bonding can be suppressed. The present invention is thereby made.

### BRIEF DESCRIPTION OF THE DRAWINGS

FIG. 1A shows the state that an intermediate layer 2 is provided on a first main face 1a of a piezoelectric material substrate 1, FIG. 1B shows the state after the intermediate layer and piezoelectric material substrate are subjected to double-side polishing, FIG. 1C shows the state that neutralized atomic beam A is irradiated onto a bonding face 2b of an intermediate layer 2A, and FIG. 1D shows the state that neutralized atomic beam B is irradiated onto a bonding face 3a of a supporting substrate 3.

FIG. 2A shows a bonded body 5, FIG. 2B shows the state that the piezoelectric material substrate of the bonded body is subjected to polishing, and FIG. 2C shows a surface acoustic element 7.

FIG. 3A shows pattern of separation in the bonded body 5, and FIG. 3B shows an outer peripheral part and an inner part of the intermediate layer 2.

### EMBODIMENTS FOR CARRYING OUT THE INVENTION

The present invention will be further described in detail below, appropriately referring to drawings.

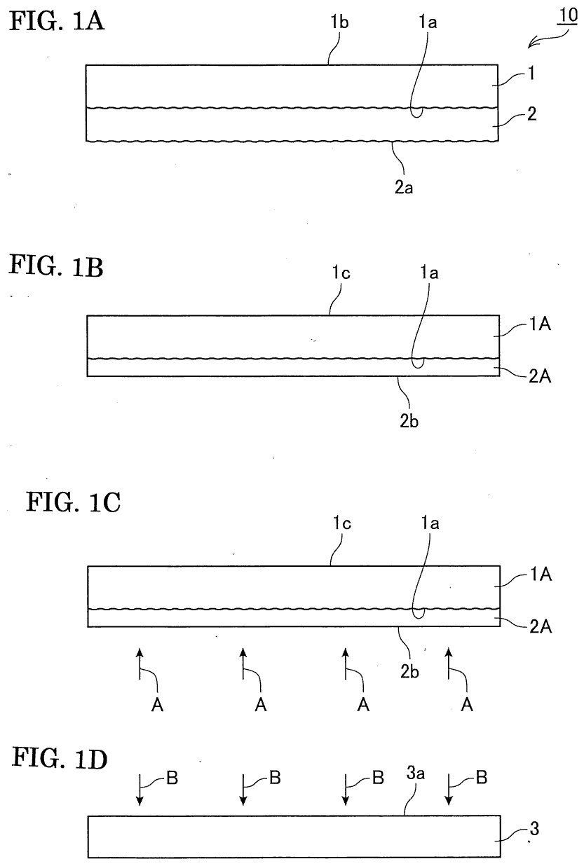

As shown in FIG. 1A, it is prepared a piezoelectric material substrate 1 having a first main face 1a and a second main face 1b. Here, the first main face 1a is made a roughened surface. Then, an intermediate layer 2 is provided on the main face 1a of the piezoelectric material substrate to produce a laminated body 10.

Then, the laminated body 10 is subjected to double-side polishing treatment. The second main face 1b of the piezoelectric material substrate 1 is thereby polished to provide a piezoelectric material substrate 1A having a polished face 1c (refer to FIG. 1B). At the same time, the surface 2a of the intermediate layer is polished to generate an intermediate layer 2A having a polished bonding face 2b.

Then, according to a preferred embodiment, neutralized beam is irradiated onto a bonding face 2b of the intermediate layer 2A as arrows A to activate the bonding face 2b.

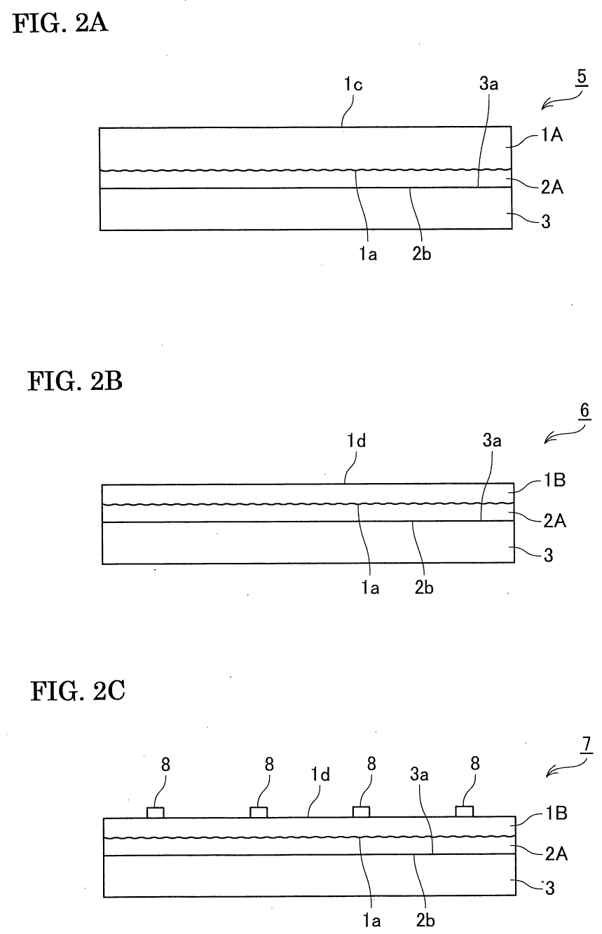

Further, as shown in FIG. 1D, neutralized beam is irradiated onto the bonding face 3a of the supporting substrate 3 as arrows B for the activation. Then, as shown in FIG. 2A, the bonding face 3a of the supporting substrate 3 and bonding face 2b of the intermediate layer 2A are subjected to direct bonding to obtain a bonded body 5.

According to a preferred embodiment, the polished face 1c of the piezoelectric material substrate 1A of the bonded body is further polished so that the thickness of the piezoelectric material substrate 1B is reduced as shown in FIG. 2B, to obtain a bonded body 6. 1d represents a polished surface.

As shown in FIG. 2C, predetermined electrodes are formed on the polished face 1d of the piezoelectric material substrate 1B to produce a surface acoustic wave element 7.

According to the present invention, during the double-side polishing step, the ratio of the average polished amount of the outer peripheral part of the intermediate layer with respect to the average polished amount of the inner part of the intermediate layer (average polished amount of the outer peripheral part/average polished amount of the inner part) is made 1.1 or higher and 1.2 or lower. Here, the respective average polished amounts are to be measured as follows.

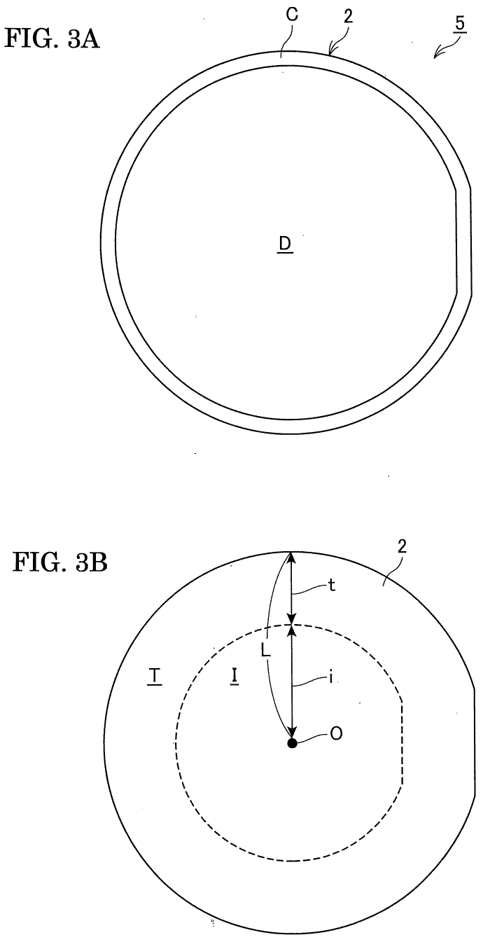

First, the outer peripheral part and inner part of the intermediate layer are defined as follows. That is, as shown in FIG. 3B, the width (radius) of the intermediate layer 2 is defined as “L”. Here, according the example of FIG. 3B, the intermediate layer 2 is not of a shape of a perfect circle and has an orientation flat. In such case, the radius of a virtual circle containing the whole of the outer profile of the intermediate layer 2 is defined as “L”. Here, the region of a width (radius) i with respect to the center “O” of the virtual circle is defined as the inner part, and the outside region of a shape substantially of a ring having a width of “t” is defined as the outer peripheral part “T”.

Here, “i” and “L” satisfy the following relationship.

$$i = 0.93 \times L$$

Then, film thicknesses of the outer peripheral part T and film thicknesses of the inner part I before and after the processing are measured by means of a microscopic spectroscopic ellipsometer (“OPTM” supplied by Otsuka Electronics Co., Ltd.), respectively. Further, as the film thickness at the roughened surface is difficult to define, the thicknesses are measured at 80 points, respectively, and the average value is defined as the film thickness.

The respective constituting elements of the present invention will be further described.

The applications of the bonded body of the present invention are not particularly limited and, for example, it may be suitably applied for an acoustic wave element or optical element.

As the acoustic wave device, a surface acoustic wave device, Lamb wave-type device, thin film resonator (FBAR) or the like is known. For example, the surface acoustic wave device is produced by providing input side IDT (Interdigital transducer) electrodes (also referred to as comb electrodes or interdigitated electrodes) for oscillating surface acoustic wave and IDT electrodes on the output side for receiving the surface acoustic wave on the surface of the piezoelectric material substrate. By applying high frequency signal on the IDT electrodes on the input side, electric field is generated between the electrodes, so that the surface acoustic wave is oscillated and propagated on the piezoelectric material substrate. Then, the propagated surface acoustic wave is drawn as an electrical signal from the IDT electrodes on the output side provided in the direction of the propagation.

A metal film may be provided on a bottom surface of the piezoelectric material substrate. After the Lamb type device is produced as the acoustic wave device, the metal film plays a role of improving the electromechanical coupling factor near the bottom surface of the piezoelectric material substrate. In this case, the Lamb type device has the structure that interdigitated electrodes are formed on the surface of the piezoelectric material substrate and that the metal film on the piezoelectric material substrate is exposed through a cavity provided in the supporting body. Materials of such metal films include aluminum, an aluminum alloy, copper, gold or the like, for example. Further, in the case that the Lamb wave type device is produced, it may be used a composite substrate having the piezoelectric material layer without the metal film on the bottom surface.

Further, a metal film and an insulating film may be provided on the bottom surface of the piezoelectric material substrate. The metal film plays a role of electrodes in the case that the thin film resonator is produced as the acoustic wave device. In this case, the thin film resonator has the structure that electrodes are formed on the upper and bottom surfaces of the piezoelectric material substrate and the insulating film is made a cavity to expose the metal film on the piezoelectric material substrate. Materials of such metal films include molybdenum, ruthenium, tungsten, chromium, aluminum or the like, for example. Further, materials of the insulating films include silicon dioxide, phosphorus silicate glass, boron phosphorus silicate glass or the like, for example.

Further, as the optical device, an optical switching device, wavelength converting device and optical modulating device may be exemplified. Further, a piezoelectric inversion structure may be formed in the piezoelectric material substrate.

The piezoelectric material substrate applied in the present invention may be made of a single crystal or polycrystal. Specifically, the material of the piezoelectric material substrate may be lithium tantalate (LT) single crystal, lithium niobate (LN) single crystal, lithium niobate-lithium tantalate solid solution single crystal, quartz, or lithium borate. Among them, LT or LN is more preferred.

Further, although the direction of the normal line to the main face of the piezoelectric material substrate is not particularly limited, for example in the case that piezoelectric material substrate is made of LT, it is preferred to use the substrate rotated from Y-axis to Z-axis by 32 to 55° (180°, 58 to 35°, 180° represented by Eiler angles) around X-axis, which is a direction of propagation of a surface acoustic wave, because of a low propagation loss. Further, in the case that the piezoelectric material substrate is made of LN, (i) it is preferred to use the substrate rotated from Z-axis to Y-axis by 37.8° (180°, 37.8°, 180° represented by Eiler angles) around X-axis, which is a direction of propagation of a surface acoustic wave, because of a high electromechanical coupling coefficient), or, (ii) it is preferred to use the substrate rotated from Y-axis to Z-axis by 40˜65° (180°, 50 to 25°, 180° represented by Eiler angles) around X-axis, which is a direction of propagation of a surface acoustic wave, because of a high sound speed. Further, although the size of the piezoelectric material substrate is not particularly limited, for example, the diameter may be 100 to 200 mm and thickness may be 0.15 to 1 μm.

The material of the supporting substrate may preferably be silicon, sapphire or quartz.

According to a preferred embodiment, the intermediate layer is composed of one or more material(s) selected from the group consisting of silicon oxide, silicon nitride, aluminum nitride, alumina, tantalum pentoxide, mullite, niobium pentoxide and titanium oxide. Although the method of forming the intermediate layer is not limited, sputtering, chemical vapor deposition (CVD) method and vapor deposition are listed.

According to the present invention, the first main face of the piezoelectric material substrate is processed to form the roughened surface. The roughened surface is defined as a surface in which periodic unevenness is formed uniformly over the plane, and the arithmetic average roughness is in a range of 0.05 μm≤Ra≤0.5 μm and the height Ry from the lowest valley bottom to the maximum mountain peak is in a range of 0.5 μm≤Ry≤5 μm. The preferred roughness is dependent on the wavelength of the acoustic wave and appropriately selected for suppressing the reflection of the bulk wave.

Further, the roughening process may be performed by methods such as grinding, polishing, etching, sand blasting or the like.

Then, the bonding face of the intermediate layer and bonding face of the supporting substrate may be polished to obtain flat surfaces. The respective flat surfaces necessarily satisfy Ra≤1 nm and 0.3 nm or lower is more preferred.

Then, neutralized beam is irradiated onto the bonding face of the intermediate layer and bonding face of the supporting substrate to activate the respective bonding faces.

When the surface activation is performed by neutralized beam, it is used a high-speed atomic beam source of saddle field type as the beam source. Then, inert gas is introduced into a chamber and a high voltage is applied onto electrodes from a direct current electric source. By this, electric field of saddle field type generated between the electrode (positive electrode) and a housing (negative electrode) causes motion of electrons, e, so that atomic and ion beams of the inert gas are generated. Among the beams reached at a grid, the ion beam is neutralized at the grid, and the beam of neutral atoms is emitted from the high-speed atomic beam source. Atomic species providing the beam may preferably be the inert gas (argon, nitrogen or the like).

In the activation step by beam irradiation, the voltage may preferably be made 0.5 to 2.0 kV, and the current may preferably be made 50 to 200 mA.

Then, the activated bonding faces are contacted and bonded with each other under vacuum atmosphere. The temperature during the bonding is ambient temperature and specifically and preferably 40° C. or lower and more preferably be 30° C. or lower. Further, the temperature during the bonding may most preferably be 20° C. or higher and 25° C. or lower. The pressure during the bonding may preferably be 100 to 20000N.

### EXAMPLES

Bonded bodies were produced according to the method described referring to FIGS. 1 to 3.

Specifically, it was applied the piezoelectric material substrate 1 composed of a lithium tantalate substrate (LT substrate) having an orientation flat part (OF part), a diameter of 6 inches and thickness of 350 μm. Further, it was applied the supporting substrate 3 composed of a silicon substrate having an OF part, a diameter of 6 inches and thickness of 230 μm. As the LT substrate, it was applied a 46° Y-cut X-propagation LT substrate, in which the propagating direction of the surface acoustic wave (SAW) is made X and the cutting angle is made rotational Y-cut plate. The main face 1a of the piezoelectric material substrate 1 and bonding face 3a of the supporting substrate 3 were subjected to mirror-surface polishing until the arithmetic average roughness Ra reached 1 nm. The arithmetic average roughness was evaluated by means of an atomic force microscope (AFM) and in a square-shaped visual field of a length of 10 μm and a width of 10 μm.

Then, the main face 1a of the piezoelectric material substrate 1 was subjected to roughening. The roughening was performed as follows.

When the main face 1a of the piezoelectric material substrate 1 is subjected to roughening, lapping is preferred. The lapping is performed by lapping process by means of rough grinding stones of GC #1000 or GC #2500. As the thus processed roughened surface was measured by “New View 7300” (supplied by Zygo corporation), values of Ra of 100 to 300 nm and Rmax of 1.4 to 4.0 μm were obtained.

Then, a sputtering system was utilized to form an intermediate layer 2 having a thickness of 6 μm on the roughened surface of the piezoelectric material substrate of 6 inches and a thickness of 350 μm. As the roughness of the bonding face 2a of the intermediate layer 2 was measured by means of a white-light interferometer (“New view” supplied by Zygo Corporation), the roughened surface had a P-V value of 2 μm. The polished amount was thus set at 2.5 μm.

Then, a carrier for double-side polishing was prepared and the laminated body 10 was set in the carrier. A urethane pad was used as the polishing pad and colloidal silica was used as the grinding stones.

After the processing, a micro-spectroscopic ellipsometer (“OPTM” supplied by Otsuka Electronics Co., Ltd.) was applied to measure the film thickness of the intermediate layer. At this time, a radius of 70 mm was set as the boundary, and the average value of the polished amount in the inner part I, the average value of the polished amount in the outer peripheral part T and the ratio were calculated. The pressure during the double-side polishing was adjusted and the thickness of the carrier was adjusted in a range of 250 to 350 μm, so that the average polished amount of the outer peripheral part/average polished amount of the inner part was adjusted as shown in table 1.

That is, as the pressure during the polishing was lowered, the inner part of the intermediate layer tends to be polished more. Contrary to this, as the pressure during the double-side polishing was made higher, the warping of the bonded body was corrected and the outer peripheral part is more susceptible to the polishing. Further, as the thickness of the carrier is made larger, the difference of the thickness of the carrier and that of the laminated body becomes smaller and the pressing of the polishing pad onto the outer peripheral part of the intermediate layer is weakened, so that the average polished amount of the outer peripheral part is lowered. On the contrary, as the thickness of the carrier is made smaller, the difference of the thickness of the carrier and that of the laminated body 10 becomes larger and the pressing of the polishing pad onto the outer peripheral part of the intermediate layer is strengthened, so that the polished amount of the outer peripheral part tends to be relatively larger.

Then, the bonding face 2b of the intermediate layer 2 and bonding face 3a of the supporting substrate 3 were cleaned to remove the contamination, followed by the incorporation into a vacuum chamber. After the vacuum suction was performed to the order of 10-6 Pa, high-speed atomic beam (acceleration voltage of 1 kV and Ar flow rate of 27 sccm) was irradiated on the bonding faces of the respective substrates over 120 sec. Then, the bonding face of the intermediate layer and bonding face of the supporting substrate were contacted with each other, followed by the bonding by pressurizing at 10000N over 2 minutes.

Then, the surface 1b of the piezoelectric material substrate 1 was ground and polished until the thickness was changed from the initial 250 μm to 3 μm.

Then, the separated portion at the interface of the intermediate layer and supporting substrate was subjected to the image-processing of the taken image of the bonded body to calculate the ratio of the area of the separated portion. Specifically, due to the difference of the contrast obtained by the image processing, the separated portion of the intermediate layer and supporting substrate was distinguished and the area of the separated portion was calculated. The ratio of the separated area with respect to the total area of the piezoelectric layer is defined as the ratio of the area of the separated portion with respect to the total area of the intermediate layer. Then, the ratio (%) of the area of the separated portion with respect to the total area of the bonding face of the intermediate layer was measured and the results were shown in table 1.

TABLE 1

| | Average polished amount | Ratio of area of |
|---|---|---|
| | of outer peripheral | separated portion |
| | part/Average polished | occupying bonding face |
| | amount of inner part | (%) |
| Inventive | 1.1 | 3.0 |
| Example 1 | | |
| Inventive | 1.2 | 3.0 |
| Example 2 | | |
| Comparative | 1.3 | 3.5 |
| Example 1 | | |
| Comparative | 1.0 | 3.5 |
| Example 2 | | |
| Comparative | 0.9 | 4.0 |
| Example 3 | | |

As a result, in the case that the ratio of the average polished amount of the outer peripheral part/average polished amount of the inner part is low and the inner part is ground more, the ratio of the area of the separated portion is increased mainly due to the separation in the outer edge. However, it is proved that the ratio of the area of the separated portion is still high even when the ratio is 1.0.

Contrary to this, in the case that the ratio of the average polished amount of the outer peripheral part/average polished amount of the inner part is in a range of 1.1 to 1.2 and that the polished amount of the outer peripheral part is slightly larger than that of the inner part, the ratio of the area of the separated portion is considerably reduced beyond expectation. However, it is proved that the ratio of the area of the separated portion is increased when the ratio exceeds 1.2.

1. A method of producing a bonded body, said method comprising;
an intermediate layer growing step of providing an intermediate layer on a first main face of a piezoelectric material substrate having said first main face and a second main face to provide a laminated body, said first main face being roughened;
a polishing step of subjecting said laminated body to double-side polishing so that said second main face of said piezoelectric material substrate and a bonding face of said intermediate layer are polished; and
a bonding step of bonding said bonding face of said intermediate layer and a supporting substrate,
wherein a ratio of an average polished amount of an outer peripheral part of said intermediate layer with respect to an average polished amount of an inner part of said intermediate layer (said average polished amount of said outer peripheral part/said average polished amount of said inner part) is 1.1 or higher and 1.2 or lower in said polishing step.

2. The method of claim 1, wherein said intermediate layer comprises a material selected from the group consisting of silicon oxide, silicon nitride, aluminum nitride, alumina, tantalum pentoxide, mullite, niobium pentoxide and titanium oxide.

3. The method of claim 1, further comprising the steps of:
irradiating neutralized beams on said bonding face of said intermediate layer and a bonding face of said supporting substrate to activate said bonding face of said intermediate layer and said bonding face of said supporting substrate, and
subjecting said bonding face of said intermediate layer and said bonding face of said supporting substrate to direct bonding.

4. The method of claim 1, wherein said piezoelectric material substrate comprises lithium niobate, lithium tantalate or lithium niobate-lithium tantalate solid solution.
